(19) United States
(12) Patent Application Publication
(10) Pub. No.: US 2014/0327139 A1
(43) Pub. Date: Nov. 6, 2014

(54) CONTACT LINER AND METHODS OF FABRICATION THEREOF

(71) Applicant: GLOBALFOUNDRIES INC., Grand Cayman (KY)

(72) Inventors: Jialin YU, Malta, NY (US); Jilin XIA, Malta (NY); Huang LIU, Mechanicville, NY (US); Wonwoo KIM, Malta, NY (US); Changyong XIAO, Mechanicville, NY (US)

(73) Assignee: GLOBALFOUNDRIES Inc., Grand Cayman (KY)

(21) Appl. No.: 13/875,377

(22) Filed: May 2, 2013

(51) Int. Cl. H01L 21/768; H01L 23/532; H01L 23/522

(52) U.S. Cl. CPC H01L 21/76843; H01L 23/5226; H01L 23/53209
USPC 257/751; 438/653

(57) ABSTRACT

Contact structures and methods of fabricating contact structures of semiconductor devices are provided. One method includes, for instance: obtaining a substrate including a dielectric layer over the substrate; patterning the dielectric layer with at least one contact opening; providing a contact liner within the at least one contact opening in the dielectric layer; and filling the contact liner with a conductive material. In enhanced aspects, providing the contact liner within the at least one contact opening includes: depositing a first layer within the at least one contact opening in the dielectric layer; depositing a second layer over the first layer within the at least one contact opening; depositing at least one intermediate layer over the second layer within the at least one contact opening; and depositing a top layer over the at least one intermediate layer within the at least one contact opening.

### FIELD OF THE INVENTION

The present invention relates to semiconductor devices and methods of fabricating semiconductor devices, and more particularly, to contact structures and methods of fabricating contact structures for semiconductor devices.

### BACKGROUND OF THE INVENTION

The contact structure (or contact or transistor contact) is the conductive layer between metallization layers and semiconductor elements in an integrated circuit. During one method of fabrication of contact structures, for instance, one or more trenches are provided with a liner and a metal fill. The liner may include a first layer, for example, titanium, and a second layer, for example, titanium nitride. The first layer has a thickness of 83 to 120 angstroms and the second layer has a thickness of 22 angstroms. The trench is then filled with tungsten by a chemical-vapor deposition (CVD) process. Then a chemical-mechanical planarization (CMP) process is performed to remove the extra tungsten and form contacts on the semiconductor.

This process is problematic for the resultant semiconductor device because the liner on the bottom of the trench is very thick and contributes to the overall contact resistance (series resistance). Further, this process creates side walls that are too thick and take over space that should be filled with tungsten which also contributes to the overall contact resistance. In addition, the thickness of the side walls creates a trench neck thickness that causes pinch-off of the trench opening which may block the tungsten fill, especially when contact size is smaller.

### BRIEF SUMMARY

The shortcomings of the prior art are overcome and additional advantages are provided through the provision, in one aspect, of a method which includes, for instance: obtaining a substrate including a dielectric layer over the substrate; patterning the dielectric layer with at least one contact opening; providing a contact liner within the at least one contact opening in the dielectric layer; and filling the contact liner with a conductive material.

In another aspect, a semiconductor device fabrication method is provided which includes: obtaining a substrate including a dielectric layer with a first dielectric, a second dielectric, and at least one contact opening; depositing a first liner layer within the at least one contact opening; depositing a second liner layer over the first liner layer within the at least one contact opening; depositing at least one intermediate liner layer over the second liner layer within the at least one contact opening; depositing an outer liner layer over the at least one intermediate liner layer within the at least one contact opening; and filling the outer layer with a conductive material.

In a further aspect, a semiconductor device is presented which includes a substrate and a plurality of contact structures disposed over the substrate. At least one contact structure of the plurality of contact structures includes a contact liner and a conductive material within the contact liner. The contact liner includes a first liner layer, a second liner layer adjacent the first liner layer, at least one intermediate liner layer adjacent the second liner layer, and a top liner layer adjacent the at least one intermediate liner layer.

Additional features and advantages are realized through the techniques of the present invention. Other embodiments and aspects of the invention are described in detail herein and are considered a part of the claimed invention.

### BRIEF DESCRIPTION OF THE SEVERAL VIEWS OF THE DRAWINGS

One or more aspects of the present invention are particularly pointed out and distinctly claimed as examples in the claims at the conclusion of the specification. The foregoing and other objects, features, and advantages of the invention are apparent from the following detailed description taken in conjunction with the accompanying drawings in which:

FIG. 1 depicts one embodiment of a process for fabricating, for instance, a transistor using a novel contact structure fabrication approach, in accordance with one or more aspects of the present invention;

FIG. 2 depicts another embodiment of a process for fabricating, for instance, a transistor using a novel contact structure fabrication approach, in accordance with one or more aspects of the present invention;

FIG. 3 depicts one embodiment of a structure obtained during a contact structure fabrication approach, in accordance with one or more aspects of the present invention;

FIG. 4 depicts the structure of FIG. 3 after patterning one or more contact openings within the dielectric layer, in accordance with one or more aspects of the present invention;

FIG. 5 depicts the structure of FIG. 4 after provision of a first layer of contact liner over the dielectric layer, in accordance with one or more aspects of the present invention;

FIG. 6 depicts the structure of FIG. 5 after provision of a second layer of contact liner over the first layer of contact liner, including within the plurality of contact openings, in accordance with one or more aspects of the present invention;

FIG. 7 depicts the structure of FIG. 6 after provision of a third layer of contact liner over the second layer of contact liner, including within the plurality of contact openings, in accordance with one or more aspects of the present invention;

FIG. 8 depicts the structure of FIG. 7 after provision of an top layer of contact liner over the third layer of contact liner, including within the plurality of contact openings, in accordance with one or more aspects of the present invention;

FIG. 9 depicts the structure of FIG. 8 after provision of a fill layer within the plurality of contact openings, in accordance with one or more aspects of the present invention; and

FIG. 10 depicts a semiconductor device with one or more contact structures, in accordance with one or more aspects of the present invention.

### DETAILED DESCRIPTION

Aspects of the present invention and certain features, advantages, and details thereof, are explained more fully below with reference to the non-limiting embodiments illustrated in the accompanying drawings. Descriptions of well-known materials, fabrication tools, processing techniques, etc., are omitted so as to not unnecessarily obscure the invention in detail. It should be understood, however, that the detailed description and the specific examples, while indicating embodiments of the invention, are given by way of illustration only, and are not by way of limitation. Various substitutions, modifications, additions and/or arrangements within the spirit and/or scope of the underlying inventive concepts will be apparent to those skilled in the art from this disclosure. Note also that reference is made below to the drawings, which are not drawn to scale for ease of understanding, wherein the same reference numbers used throughout different figures designate the same or similar components.

Generally stated, disclosed herein are certain novel contact structure formation processes, and contact structures, which provide significant advantages over the above-noted, existing contact structure fabrication processes and structures. Advantageously, the contact structure formation processes disclosed herein may improve barrier strength to prevent metal diffusion and fluorine attack. Additionally, as explained herein, by reducing the barrier layer or contact liner extra space is provided in the critical dimension for filling the contact liner with conductive material to lower the contact resistance. Also, since the barrier layer or contact liner thickness is reduced, the risk of overhang by the contact liner is reduced and the tungsten (W) fill process margin is larger and the seam size during W deposition can be reduced.

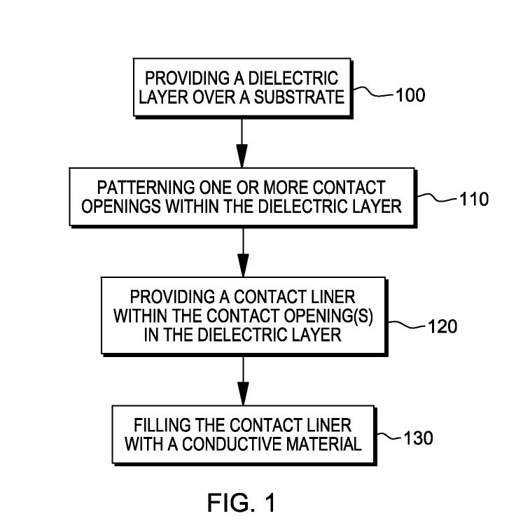

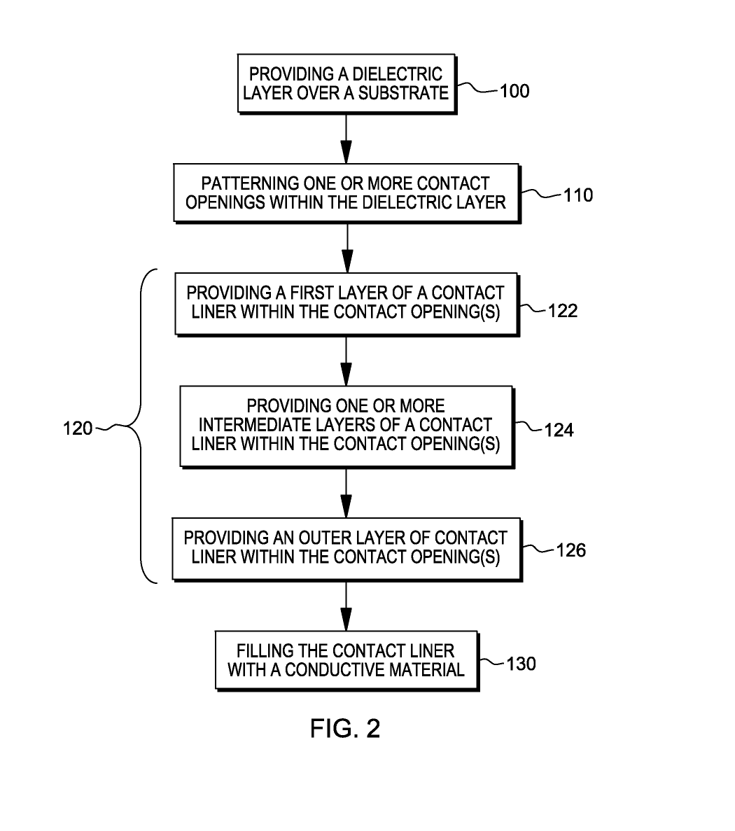

In one aspect, in one embodiment, as shown in FIG. 1, contact formation in accordance with one or more aspects of the present invention may include, for instance: providing a dielectric layer over a substrate 100; patterning one or more contact openings within the dielectric layer 110; providing a contact liner within the contact opening in the dielectric layer 120; and filling the contact liner with a conductive material 130. This process is inherent in the more detailed contact structure formation process approach of FIG. 2.

The contact liner provided within the contact opening in the dielectric layer 120, of FIG. 1, in one aspect disclosed herein may include: providing a first layer of a contact liner within the contact opening(s) 122; providing one or more intermediate layers of a contact liner within the contact opening(s) 124; and providing an outer layer of contact liner within the contact opening(s) 126.

As illustrated in FIG. 2, in an embodiment, contact formation in accordance with one or more aspects of the present invention may include: providing a dielectric layer over a substrate 100 and patterning one or more contact openings within the dielectric layer 110. Providing a first contact liner layer within the contact openings 122 of the dielectric layer. If desired, one or more intermediate contact liner layers may be provided within the contact openings 124 in the dielectric layer. Further, a top or outer contact liner layer may be provided within the contact openings 126. In addition, a conductive material may be filled into the top contact liner layer within the contact opening 130.

By way of specific example, the dielectric layer 204 may be, in one embodiment, selective to silicon and nitride etching processes, and may include, for instance, an oxide layer or an organic layer 207 and a nitride layer 208, for example, a silicon nitride layer. Advantageously, the contact structure formation processes disclosed herein provide similar or identical outer dimensions (or profiles) for both NFET and PFET devices.

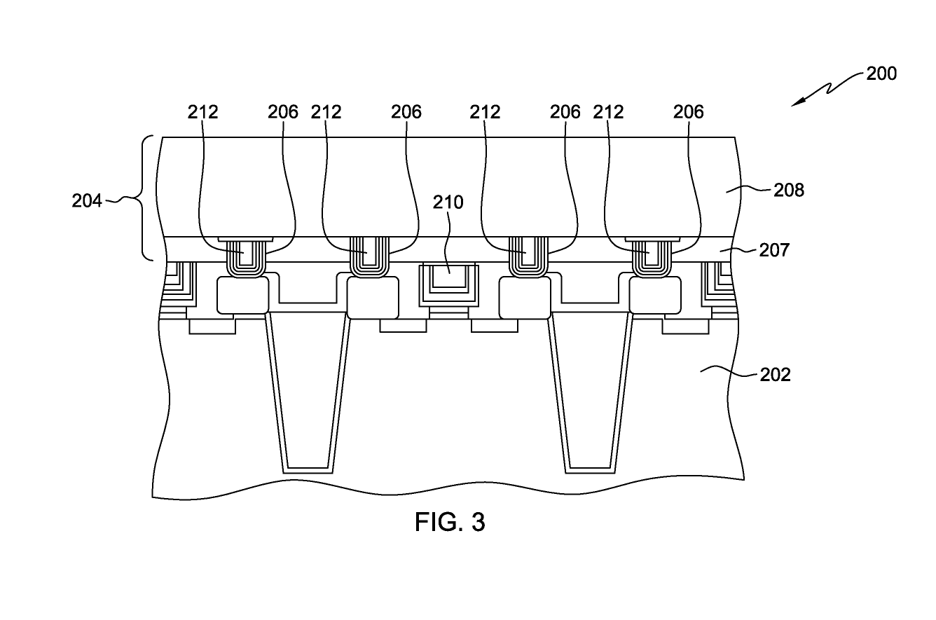

FIGS. 3-10 depict, by way of example only, one detailed embodiment of a contact structure formation process, and resultant contact structure, in accordance with one or more aspects of the present invention. Note again that these figures are not drawn to scale in order to facilitate understanding of the invention, and that the same reference numerals used throughout different figures designate the same or similar elements.

FIGS. 3-10 schematically illustrate an intermediate circuit structure 200 at several intermediate stages of manufacturing. As depicted in FIG. 3, the intermediate structure 200 may include a substrate 202 which may include, for example, a semiconductor material. The semiconductor material may include, e.g., silicon, germanium, a compound semiconductor material, a layered semiconductor material, a silicon-on-insulator (SOI) material, a SiGe-on-insulator (SGOI) material, a germanium-on-insulator (GOI) material, and/or the like. A dielectric layer 204 may be deposited using conventional deposition processes, such as chemical-vapor deposition (CVD), atomic layer deposition (ALD), physical layer deposition (PVD), or plasma-enhanced versions of such processes.

The intermediate structure 200 can further include one or more layers of conductive materials, dielectric materials, and/or semiconductor materials formed over substrate 202 using a variety of techniques including, e.g., patterning by lithography and subsequent etching, for fabricating a plurality of contact openings. The intermediate circuit structure 200 may also include devices, for example, gates 210, sources, drains and the like, which may be disposed over the substrate 202 in the one or more layers. In addition, the intermediate circuit structure 200 may include a dielectric layer 204 disposed over the substrate 202 and any additional layers which may already be formed over the substrate 202. The dielectric layer 204 may include a material different from the material of the substrate 202. The dielectric layer 204 may include for example, two layers, a first layer or first dielectric 207 and a second layer or second dielectric 208. The first and second layers 207, 208 may be, for example an oxide layer and a nitride layer, respectively. The dielectric layer 204 may be, for example, a non-conductive dielectric layer. As depicted in FIGS. 3-10, a first set of contacts may be created with multiple layers of liner 220 in the openings 206 in the first dielectric 207 of the dielectric layer 204. Advantageously, the height of the resultant contact structure(s) may correlate, in one embodiment, to the thickness of the first dielectric 207 of the dielectric layer 204.

During manufacturing, additional openings 206 may be formed in the second layer 208 of the dielectric layer 204 using a variety of techniques including e.g. patterning by lithography and subsequent etching. Advantageously, as noted further below, the height of the resultant contact structure(s) may correlate, in one embodiment, to the thickness of the second layer 208 of the dielectric layer 204 and in another embodiment, to the thickness of the first and second layers 207, 208 of the dielectric layer 204. Thus, the thickness of the entire dielectric layer 204 and/or the thickness of the second dielectric 208 of the dielectric layer 204 may be chosen, for example, based on the desired height of the contact structure(s).

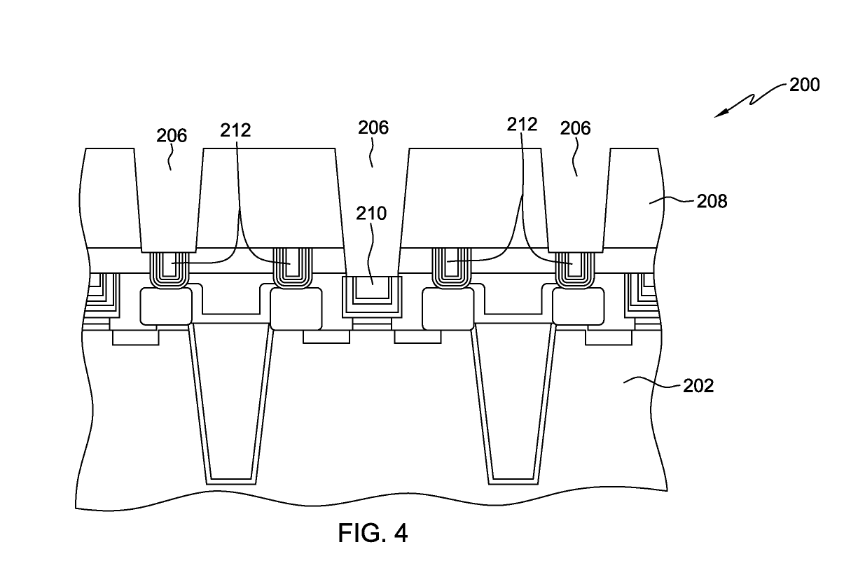

As shown in FIG. 4, a plurality of openings 206 can be formed within the dielectric layer 204 of the intermediate structure 200 using a variety of techniques, including, e.g., patterning by lithography and subsequent etching. The openings 206 may be formed in the dielectric layer 204, for example, openings 206 may be formed in the first layer 207, in the second layer 208, or through both the first and second layers 207, 208. The openings 206 formed through both the first and second layers 207, 208 may, for example, land on a gate 210. The openings 206 formed in only the second layer 208 may, for example, land on the contacts 212 formed in the openings 206 in the first layer 207.

Those skilled in the art will note from the description provided herein that the footprint of the openings 206 corresponds to the footprint of the resultant contact electrode formed within that opening 206. As such, by forming openings 206 of identical footprint, a plurality of resultant contact electrodes are defined within those openings 206 having identical footprints as well. However, the openings 206 may have different footprints resulting in the resultant contact electrodes having different footprints. Still further, as noted above, in one implementation, the height of the dielectric layer 204 or at least one portion of the dielectric layer 204 may determine the height of the contact electrodes, and thus, the height of the resultant contact electrodes may be identical as well, notwithstanding that the composition of the contact electrodes may be different, for instance, as needed for the different contact structures of a semiconductor device having both NFETs and PFETs.

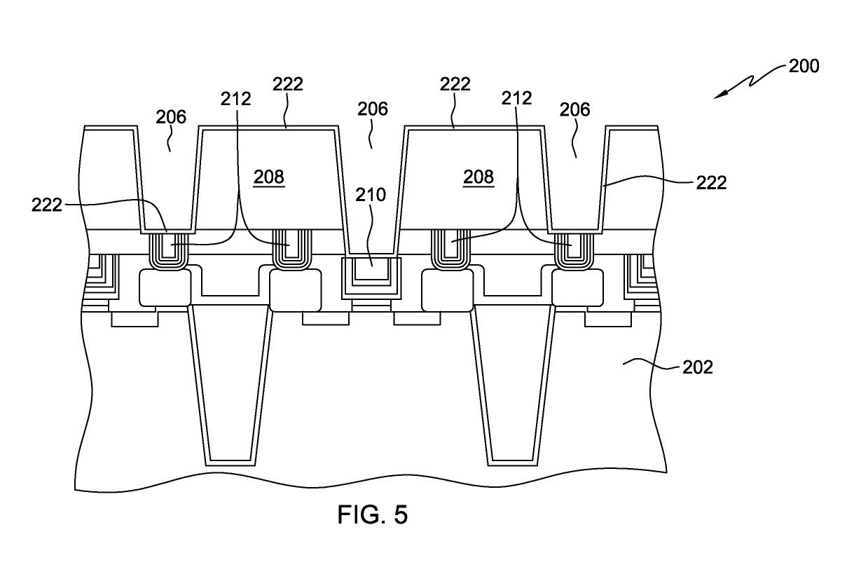

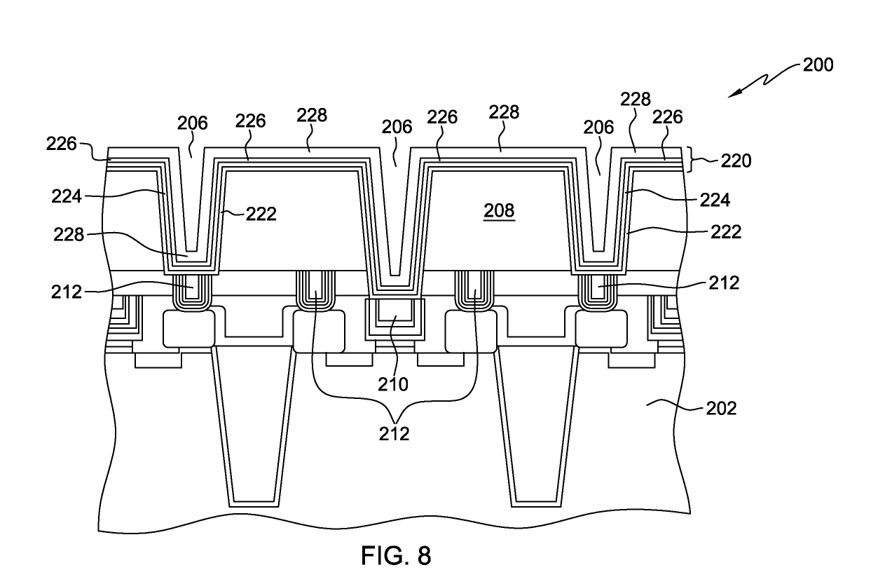

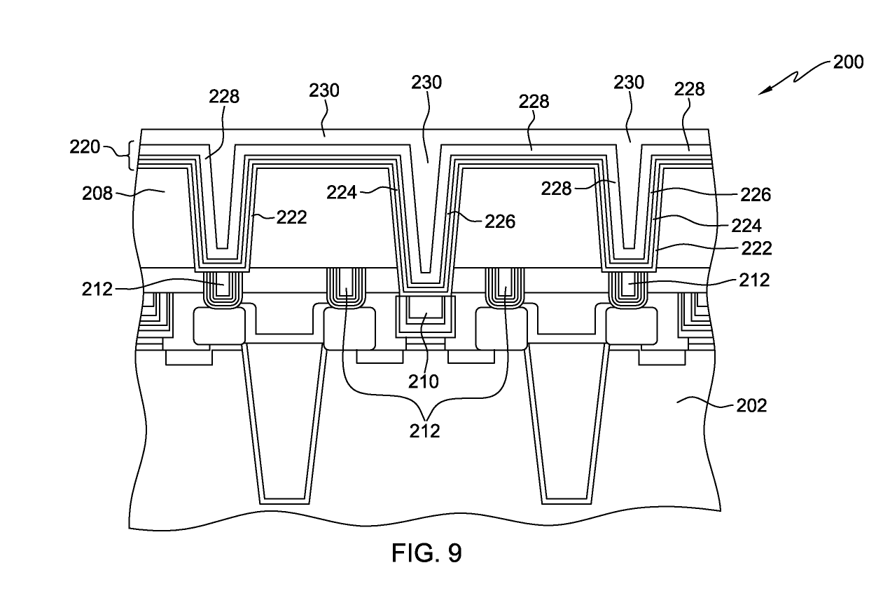

One or more layers of a liner 220 (see FIGS. 8-9), for example, titanium nitride/titanium (TiN/Ti) liner, can be deposited into the openings 206. As used herein “liner,” “layers,” “contact liners,” or “contact layers” refer generally to any film or layer which may include part of the contact structure, and includes (for instance) one or more conformally-deposited layers. FIGS. 5-8 depict, by way of example only, four layers of a liner 220 being deposited into the openings 206. Although only four contact layers of liner 220 are illustrated it is contemplated that any number of layers of liner 220 may be deposited into the openings 206 depending on the thickness of the layers and the size of the openings 206. The liner 220 will generally have an even number of layers as it is contemplated that for every layer of a first material that is applied to the openings 206 a corresponding layer of a second material will be deposited. By way of example, the first material may be titanium and the second material may be titanium nitride. The thickness of the liner layers may vary, depending upon the particular application, composition, and number of layers, as well as the size of the openings 206.

As depicted in FIG. 5, in one embodiment, the contact formation process includes conformally depositing a first layer 222 of liner 220 into the openings 206, for instance, using conventional deposition processes. The terms “first layer” and “first liner layer” may be used interchangeably as they essentially describe the same element. In the depicted embodiment, a first set of openings 206 are present in the first layer 207 of the dielectric layer 204. The first layer 222 may be an adhesive layer and in the depicted embodiment, the first layer 222 may be, for example, a titanium (Ti) layer. Alternatively, the first layer 222 may be, for example, a carbon doped titanium, a fluorine free tungsten (W), a tungsten nitride (WN), or titanium nitride (TiN). The first layer 222 may be a material with good adhesion properties to the dielectric layer 204 to assist the liner 220 in bonding to the dielectric layer 204. The first layer 222 may have a thickness ranging from, for example, about 2 Å to about 20 Å, and more preferably from about 5 Å to about 10Å for an opening 206 of, for example, 20 nm by 70 nm.

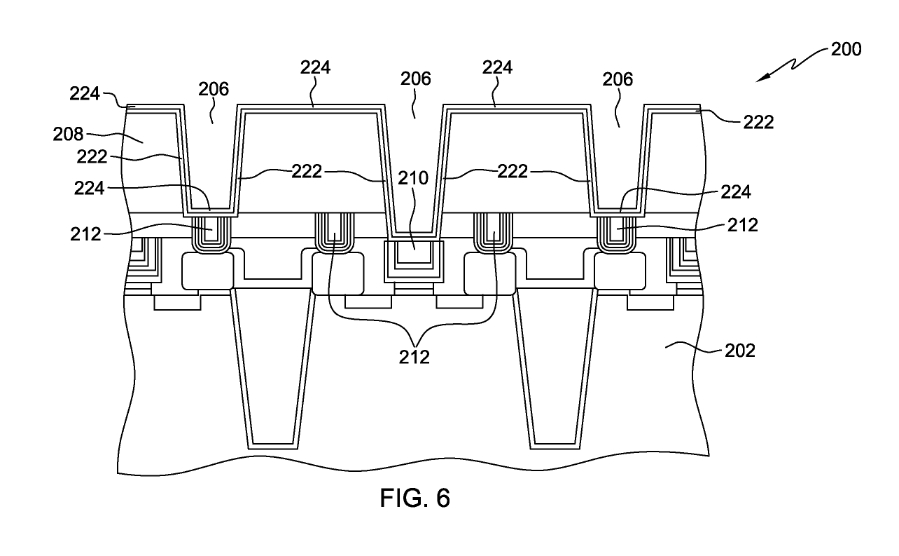

A second layer 224 of liner 220 may be deposited into the openings 206 onto the first layer 222, as shown in FIG. 6. The terms “second layer” and “second liner layer” may be used interchangeably as they essentially describe the same element. The second layer 224 may be a barrier layer, which may be, for example, a titanium nitride (TiN) layer. Alternatively, the second layer 224 may be, for example, titanium (Ti), a fluorine free tungsten nitride (WN), a fluorine free tungsten layer (W), tantalum nitride (TaN), titanium aluminum nitride (TiAIN), and the like. The second layer 224 may have a thickness ranging from, for example, about 2 Å to about 20 Å, and more preferably from about 5 Å to about 10 Å for an opening 206 of, for example, 20 nm by 70 nm. In one embodiment, by way of example only, the first layer 222 is Ti and the second layer 224 is TiN, thereby creating ionic bonds between the layers to provide a stronger barrier layer.

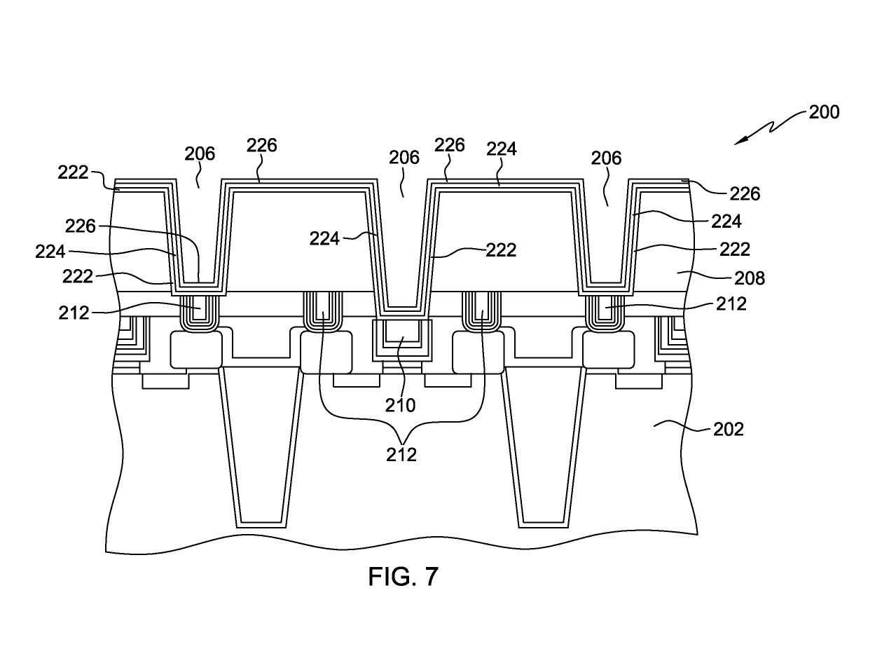

As depicted in FIG. 7, a third layer 226 of liner 220 is deposited into the openings 206 onto the second layer 224. The terms “third layer,” “third liner layer,” and “intermediate layer” may be used interchangeably as they essentially describe the same element. The third layer 226 may be another adhesive layer. The third layer 226 may be, for example, a Ti layer a carbon doped Ti layer, a fluorine free W layer, or a TiN, of the type described above with reference to the first layer 222 and for brevity sake will not be described again here. The third layer 226 may have a thickness ranging from, for example, about 2 Å to about 20 Å, and more preferably from about 5 Å to about 10 Å for an opening 206 of, for example, 20 nm by 70 nm. Although not depicted in the specific example shown in FIGS. 3-10, a plurality of additional second and third layers 224, 226 may be applied to the third layer 226 of FIG. 7 and the number of additional layers may depend upon the particular application and the size of the openings 206. The plurality of additional layers may also have a thickness ranging from, for example, about 2 Å to about 20 Å, and more preferably from about 5 Å to about 10 Å for an opening 206 of, for example, 20 nm by 70 nm. In one embodiment, the plurality of additional layers is an even number.

FIG. 8 depicts a top layer 228 of liner 220 deposited into the openings 206 over the third layer 226. The terms “top layer,” “top liner layer,” “outer layer” and “outer liner layer” may be used interchangeably as they essentially describe the same element. The top layer 228 of the liner 220 may be another barrier layer. The top layer 228 may be, for example, a TiN layer, a fluorine free WN layer or a Ti layer, of the type described above with reference to the second layer 224 and for brevity sake will not be described again here. The top layer 224 may have a thickness ranging from, for example, approximately 5 Å to approximately 25 Å and more preferably, approximately 15 Å.

In one embodiment, the layers 222, 224, 226, and 228 may be deposited in cycles alternating between a first material or adhesive layer, for example, Ti, a carbon doped Ti, a fluorine free W, or a TiN, and a second material or barrier layer, for example, a TiN, a fluorine free WN, or a Ti. By way of example only, the layers 222 and 226 may be, for example, Ti and the layers 224 and 228 may be, for example, TiN. Additional layers of Ti and TiN may also be deposited between layers 226 and 228 to create a liner 220 of at least four layers of Ti and TiN, wherein the at least four layers are an even number. In one example, a liner 220 may include four layers, as shown in FIGS. 3-10, wherein the first layer 222 is 13 Å of Ti, the second layer 224 is 8 Å of TiN, the third layer 226 is 13 Å of Ti, and the outer layer 228 is 15 Å of TiN. In another example, a liner 220 may include six layers with the first, third and fifth layers being 8 Å of Ti, the second and fourth layers being 8 Å of TiN, and the sixth layer being 15 Å of TiN.

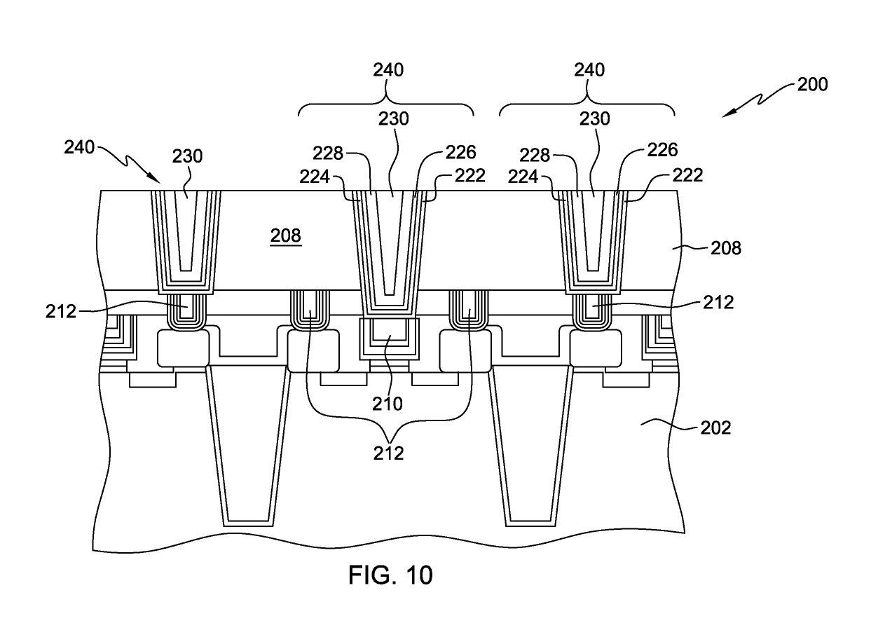

The liner 220 in the openings 206 may then be filled with a conductive material 230, as shown in FIG. 9. As noted, the conductive material or contact material 230 may include a metal, such as, for example, tungsten (W), aluminum (Al), copper (Cu), cobalt (Co), titanium (Ti), and alloys of one or more of these metals and may be conformally deposited over the contact liner 220 using processes, such as for instance, PVD or CVD. The conductive material 230 may be inserted into the openings 206 using a variety of techniques, such as low resistivity tungsten (LRW process) or pulsed nucleation layer (PNLxT) process, followed by a chemical vapor deposition (CVD) of tungsten (W) process (or CVD-W process). The excess conductive material 230 and excess contact layers 222, 224, 226, 228 may be polished away using, for example, a chemical-mechanical planarization (CMP) process. The chemical-mechanical polishing may terminate at the dielectric layer 204, resulting (as noted) in the height of the contact structures 240 being substantially equal to the thickness of the dielectric layer 204 or the thickness of the second layer 208 of the dielectric layer 204, as illustrated in FIG. 10. Thus, in accordance with this approach, by selecting the thickness of the dielectric layer and controlling the CMP removal amount, it is possible to accurately select the height of the contact structures 240.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include” (and any form of include, such as “includes” and “including”), and “contain” (and any form contain, such as “contains” and “containing”) are open-ended linking verbs. As a result, a method or device that “comprises”, “has”, “includes” or “contains” one or more steps or elements possesses those one or more steps or elements, but is not limited to possessing only those one or more steps or elements. Likewise, a step of a method or an element of a device that “comprises”, “has”, “includes” or “contains” one or more features possesses those one or more features, but is not limited to possessing only those one or more features. Furthermore, a device or structure that is configured in a certain way is configured in at least that way, but may also be configured in ways that are not listed.

The corresponding structures, materials, acts, and equivalents of all means or step plus function elements in the claims below, if any, are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of one or more aspects of the invention and the practical application, and to enable others of ordinary skill in the art to understand one or more aspects of the invention for various embodiments with various modifications as are suited to the particular use contemplated.

What is claimed is:

1. A method comprising:
obtaining a substrate including a dielectric layer over the substrate;
patterning the dielectric layer with at least one contact opening;
providing a contact liner within the at least one contact opening in the dielectric layer; and
filling the contact liner with a conductive material.

2. The method of claim 1, wherein providing the contact liner within the at least one contact opening comprises:
depositing a first layer within the at least one contact opening in the dielectric layer;
depositing a second layer over the first layer within the at least one contact opening;
depositing at least one intermediate layer over the second layer within the at least one contact opening; and
depositing a top layer over the at least one intermediate layer within the at least one contact opening.

3. The method of claim 2, wherein the first layer comprises one of a titanium, a carbon doped titanium, a fluorine free tungsten or a titanium nitride.

4. The method of claim 3, wherein the second layer comprises one of a titanium nitride, a fluorine free tungsten nitride, or a titanium.

5. The method of claim 4, wherein the at least one intermediate layer comprises one of a titanium, a fluorine free tungsten, or a titanium nitride.

6. The method of claim 5, wherein the top layer comprises one of a titanium, a carbon doped titanium, a fluorine free tungsten, a tungsten nitride, or titanium nitride.

7. The method of claim 2, wherein the at least one intermediate layer comprises one of a titanium, a carbon doped titanium, a fluorine free tungsten, a titanium nitride, or a fluorine free tungsten nitride.

8. The method of claim 2, wherein the first layer comprises a thickness ranging from about 2 angstroms to 20 angstroms.

9. The method of claim 2, wherein the second layer comprises a thickness ranging from about 2 angstroms to 20 angstroms.

10. The method of claim 2, wherein the at least one intermediate layer comprises a thickness ranging from about 2 angstroms to 20 angstroms.

11. The method of claim 2, wherein the top layer comprises a thickness of about 5 angstroms to 25 angstroms.

12. The method of claim 2, wherein the top layer comprises a thickness of about 15 angstroms.

13. A semiconductor device fabrication method comprising:
obtaining a substrate including a dielectric layer with a first dielectric, a second dielectric, and at least one contact opening;
depositing a first liner layer within the at least one contact opening;
depositing a second liner layer over the first liner layer within the at least one contact opening;
depositing at least one intermediate liner layer over the second liner layer within the at least one contact opening;
depositing an outer liner layer over the at least one intermediate liner layer within the at least one contact opening; and
filling the outer liner layer with a conductive material.

14. The semiconductor device fabrication method of claim 13, wherein the at least one intermediate liner layer comprises a third liner layer, a fourth liner layer, and a fifth liner layer.

15. The semiconductor device fabrication method of claim 14, wherein the first liner layer, third liner layer, and fifth liner layer are titanium and the second liner layer, fourth liner layer, and outer liner layer are titanium nitride.

16. The semiconductor device fabrication method of claim 15, wherein the first liner layer, second liner layer, third liner layer, fourth liner layer, and fifth liner layer each include a thickness ranging from of 2 angstroms to 20 angstroms.

17. The semiconductor device fabrication method of claim 16, wherein the outer liner layer includes a thickness of about 5 angstroms to 20 angstroms.

18. The semiconductor device fabrication method of claim 16, wherein the outer liner layer includes a thickness of about 15 angstroms.

19. A semiconductor device comprising:
a substrate;
a plurality of contact structures disposed over the substrate, at least one contact structure of the plurality of contact structures comprising a contact liner and a conductive material within the contact liner, wherein the contact liner comprises a first liner layer, a second liner layer adjacent the first liner layer, at least one intermediate liner layer adjacent the second liner layer, and a top liner layer adjacent the at least one intermediate liner layer.

20. The semiconductor device of claim 19, wherein the first liner layer is titanium, the second liner layer is titanium nitride, the at least one intermediate liner layer is titanium, and the top liner layer is titanium nitride.
